(19) United States
(12) Patent Application Publication
(10) Pub. No.: US 2022/0278209 A1
(43) Pub. Date: Sep. 1, 2022

(54) HIGH VOLTAGE FIELD EFFECT TRANSISTORS WITH METAL-INSULATOR-SEMICONDUCTOR CONTACTS AND METHOD OF MAKING THE SAME

(71) Applicant: SANDISK TECHNOLOGIES LLC, ADDISON, TX (US)

(72) Inventors: Teruyuki MINE, Yokkaichi (JP); Hiroyuki OGAWA, Yokkaichi (JP); Masashi ISHIDA, Yokkaichi (JP)

(21) Appl. No.: 17/188,271

(22) Filed: Mar. 1, 2021

(51) Int. Cl. H01L 29/417; H01L 27/11524; H01L 27/11556; H01L 27/1157; H01L 27/11582; H01L 29/08

(52) U.S. Cl. CPC H01L 29/41741; H01L 27/11524; H01L 27/11556; H01L 27/1157; H01L 27/11582; H01L 29/0847

(57) ABSTRACT

A semiconductor structure includes a high voltage field effect transistor having metal-insulator-semiconductor active region contact structures and a low voltage field effect transistor having metal-semiconductor active region contact structures, and at least one of a smaller gate dielectric thickness or a smaller gate length than the high voltage field effect transistor.

### FIELD

The present disclosure relates generally to the field of semiconductor devices and specifically to high voltage field effect transistors including metal-insulator-semiconductor (MIS) contacts and methods of making the same.

### BACKGROUND

Prior art high voltage field effect transistors often suffer from surface breakdown voltage. Such transistors often have a complex extended low doped drain (LDD) structure to improve surface breakdown characteristics at the expense of process complexity and increased cost.

### SUMMARY

According to an aspect of the present disclosure, a semiconductor structure includes a high voltage field effect transistor having metal-insulator-semiconductor active region contact structures and a low voltage field effect transistor having metal-semiconductor active region contact structures, and at least one of a smaller gate dielectric thickness or a smaller gate length than the high voltage field effect transistor.

According to another aspect of the present disclosure, a method of forming a semiconductor structure includes forming a first gate structure of a first field effect transistor and a second gate structure of a second field effect transistor over a semiconductor material layer; forming a first source region and a first drain region of the first field effect transistor and a source extension region and a drain extension region of the second field effect transistor within the semiconductor material layer; forming a deep source region and a deep drain region of the second field effect transistor within the semiconductor material layer; forming a contact-level dielectric layer over the first gate structure, the second gate structure, and the semiconductor material layer; forming contact via cavities through the contact-level dielectric layer over the first source region, the first drain region, the deep source region, and the deep drain region; forming a source-side dielectric liner on the first source region and forming a drain-side dielectric liner on the first drain region; and forming contact via structures in the contact via cavities, wherein the contact via structures comprise a first source contact via structure overlying the first source region and vertically spaced from the first source region by the source-side dielectric liner, a first drain contact via structure overlying the first drain region and vertically spaced from the first drain region by a drain-side dielectric liner, a second source contact via structure contacting a top surface of the deep source region, and a second drain contact via structure contacting a top surface of the deep drain region.

### BRIEF DESCRIPTION OF THE DRAWINGS

FIG. 1 is a vertical cross-sectional view of an exemplary structure after formation of shallow trench isolation structures and a first gate dielectric layer according to an embodiment of the present disclosure.

FIG. 2 is a vertical cross-sectional view of the exemplary structure after patterning the first gate dielectric layer according to an embodiment of the present disclosure.

FIG. 3 is a vertical cross-sectional view of the exemplary structure after formation of a second gate dielectric layer according to an embodiment of the present disclosure.

FIG. 4 is a vertical cross-sectional view of the exemplary structure after deposition of a gate electrode layer and a gate cap dielectric layer according to an embodiment of the present disclosure.

FIG. 5 is a vertical cross-sectional view of the exemplary structure after formation of gate stack structures according to an embodiment of the present disclosure.

FIG. 6 is a vertical cross-sectional view of the exemplary structure after formation of lightly-doped source/drain regions according to an embodiment of the present disclosure.

FIG. 7 is a vertical cross-sectional view of the exemplary structure after formation of heavily-doped source/drain regions according to an embodiment of the present disclosure.

FIG. 8 is a vertical cross-sectional view of the exemplary structure after formation of a contact-level dielectric layer according to an embodiment of the present disclosure.

FIG. 9 is a vertical cross-sectional view of the exemplary structure after formation of a continuous dielectric liner according to an embodiment of the present disclosure.

FIG. 10 is a vertical cross-sectional view of the exemplary structure after patterning the continuous dielectric liner into various dielectric liners according to an embodiment of the present disclosure.

FIG. 11 is a vertical cross-sectional view of the exemplary structure after formation of contact via structures according to an embodiment of the present disclosure.

FIG. 12 is a vertical cross-sectional view of an alternative embodiment of the exemplary structure after forming various dielectric liners according to an embodiment of the present disclosure.

FIG. 13 is a vertical cross-sectional view of the alternative embodiment of the exemplary structure after formation of contact via structures according to an embodiment of the present disclosure.

FIG. 14 is a schematic vertical cross-sectional view the exemplary structure after formation of a three-dimensional memory array over the field effect transistors according to an embodiment of the present disclosure.

### DETAILED DESCRIPTION

Embodiments of the present disclosure are directed to high voltage field effect transistors including metal-insulator-semiconductor (MIS) contacts and methods of making the same, the various aspects of which are now described in detail.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single element and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a first element is “electrically connected to” a second element if there exists a conductive path consisting of at least one conductive material between the first element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

As used herein, a “layer stack” refers to a stack of layers. As used herein, a “line” or a “line structure” refers to a layer that has a predominant direction of extension, i.e., having a direction along which the layer extends the most.

As used herein, a “semiconducting material” refers to a material having electrical conductivity in the range from 1.0×10⁻⁶ S/cm to 1.0×10⁵ S/cm. As used herein, a “semiconductor material” refers to a material having electrical conductivity in the range from 1.0×10⁻⁶ S/cm to 1.0×10⁵ S/cm in the absence of electrical dopants therein, and is capable of producing a doped material having electrical conductivity in a range from 1.0 S/cm to 1.0×10⁵ S/cm upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/cm. As used herein, an “insulator material”, “insulating material” or a “dielectric material” refers to a material having electrical conductivity less than 1.0×10⁻⁶ S/cm. As used herein, a “heavily doped semiconductor material” refers to a semiconductor material that is doped with electrical dopant at a sufficiently high atomic concentration to become a conductive material, i.e., to have electrical conductivity greater than 1.0×10⁵ S/cm. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁶ S/cm to 1.0×10⁵ S/cm. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material can be semiconducting or conductive depending on the atomic concentration of electrical dopants therein. As used herein, a “metallic material” refers to a conductive material including at least one metallic element therein. All measurements for electrical conductivities are made at the standard condition.

As used herein, a “field effect transistor” refers to any semiconductor device having a semiconductor channel through which electrical current flows with a current density modulated by an external electrical field. As used herein, a “channel region” refers to a semiconductor region in which mobility of charge carriers is affected by an applied electrical field. A “gate electrode” refers to a conductive material portion that controls electron mobility in the channel region by application of an electrical field. A “source region” refers to a doped semiconductor region that supplies charge carriers that flow through the channel region. A “drain region” refers to a doped semiconductor region that receives charge carriers supplied by the source region and passes through the channel region. An “active region” refers to a source region of a field effect transistor or a drain region of a field effect transistor. A “source extension region” refers to a doped semiconductor region having a lesser dopant concentration than, and having a same type of doping as, a source region and including a portion disposed between the source region and the channel region. A “drain extension region” refers to a doped semiconductor region having a lesser dopant concentration than, and having a same type of doping as, a drain region and including a portion disposed between the drain region and the channel region. An “active region extension” refers to a source extension region or a drain extension region.

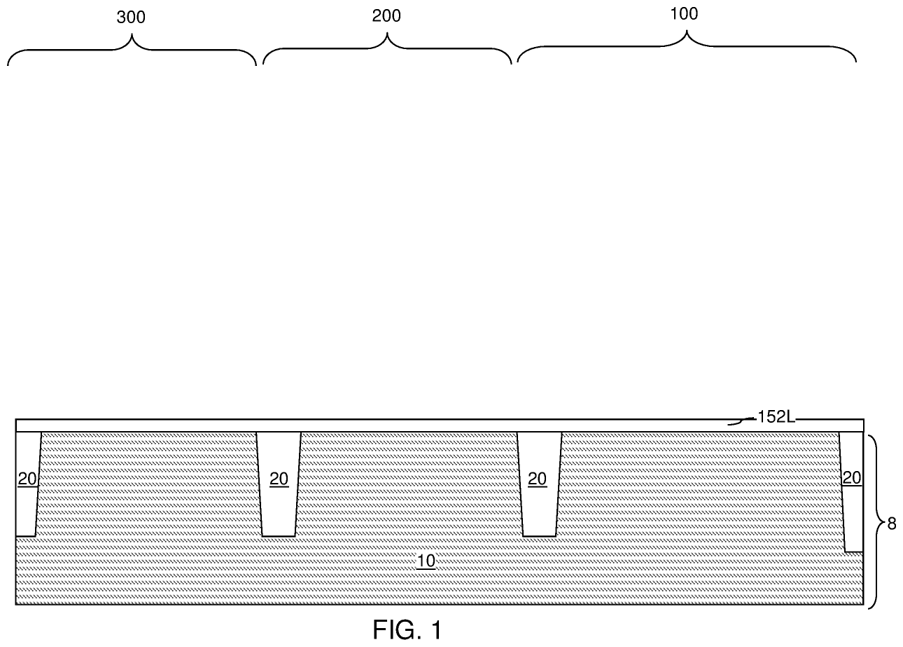

Referring to FIG. 1, an exemplary structure according to an embodiment of the present disclosure is illustrated. The exemplary structure may include many device regions, which can include, for example, a first device region 100, a second device region 200, and a third device region 300 located over a semiconductor substrate 8. As used herein, a “semiconductor substrate” refers to a substrate that includes at least one semiconductor material portion, i.e., at least one portion of a semiconductor material.

The semiconductor substrate 8 includes a semiconductor material layer 10. The semiconductor substrate 8 may optionally include at least one additional material layer at a bottom portion thereof. In one embodiment, the semiconductor substrate 8 can be a bulk semiconductor substrate consisting of the semiconductor material layer 10 (e.g., single crystal silicon wafer), or can be a semiconductor-on-insulator (SOI) substrate including a buried insulator layer (such as a silicon oxide layer) underlying the semiconductor material layer 10, and a handle substrate underlying the buried insulator layer. Alternatively, the semiconductor material layer 10 may comprise an epitaxial semiconductor (e.g., single crystal silicon) layer deposited on a semiconductor substrate (e.g., silicon wafer) 8 or may comprise a doped well (e.g., doped silicon well) in the upper portions of the semiconductor substrate (e.g., silicon wafer) 8.

The semiconductor material layer 10 can include a lightly doped semiconductor material portion (e.g., silicon portion) on which at least one field effect transistor can be formed. In one embodiment, the entirety of the semiconductor material in the semiconductor material layer 10 may include the lightly doped semiconductor material. In another embodiment, the lightly doped semiconductor material can be a semiconductor well embedded within another semiconductor material having a different dopant concentration and optionally, a doping of the opposite conductivity type. The dopant concentration of the lightly doped semiconductor material portion may be optimized for a body region of the at least one field effect transistor to be subsequently formed. For example, the lightly doped semiconductor material portion may include electrical dopants at an atomic concentration in a range from 1.0×10¹⁴/cm³ to 1.0×10¹⁸/cm³, such as from 1.0×10¹⁵/cm³ to 1.0×10¹⁷/cm³, although lesser and greater atomic concentrations can also be employed. The conductivity type of the portion of the semiconductor material layer 10 to be subsequently employed as a body region of a field effect transistor is herein referred to as a first conductivity type, which may be p-type for an n-type field effect transistor or n-type for a p-type field effect transistor.

The semiconductor material of the semiconductor material layer 10 can be an elemental semiconductor material (such as silicon) or an alloy of at least two elemental semiconductor materials (such as a silicon-germanium alloy), or can be a compound semiconductor material (such as a III-V compound semiconductor material or a II-VI compound semiconductor material), or can be an organic semiconductor material. The thickness of the semiconductor material layer 10 can be in a range from 0.5 mm to 2 mm in case the semiconductor material layer 10 is a bulk semiconductor substrate. In case the semiconductor material layer 10 is a semiconductor-on-insulator substrate, the thickness of the top semiconductor material layer within the semiconductor material layer 10 may be in a range from 100 nm to 1,000 nm, although lesser and greater thicknesses can also be employed.

Pad layers (not shown) such as a stack of a silicon oxide layer and a silicon nitride layer can be deposited over the top surface of the semiconductor material layer 10, and can be lithographically patterned to cover each device region, i.e., each region in which semiconductor devices are to be subsequently formed. An anisotropic etch process can be performed to etch shallow trenches that vertically extend through the pad layers and into an upper portion of the semiconductor material layer 10. The photoresist layer can be employed as an etch mask layer during the anisotropic etch process. The depth of the shallow trenches, as measured from the horizontal plane including the top surface of the semiconductor material layer 10, can be in a range from 300 nm to 3 microns, although lesser and greater depths may also be employed. The shallow trenches can be interconnected among one another to provide multiple device regions that correspond to a respective unetched portion of the semiconductor material layer 10. The multiple device regions include a first device region 100 in which a high voltage field effect transistor is subsequently formed, an optional second device region 200 in which a medium voltage field effect transistor is subsequently formed, and a third device region 300 in which a low voltage field effect transistor is to be subsequently formed. The high voltage field effect transistor is configured to operate at a higher voltage than the medium and low voltage field effect transistors. The medium voltage field effect transistor (if present) is configured to operate at a higher voltage than the low voltage field effect transistor.

While the present disclosure illustrates a single field effect transistor per device region, it is understood that multiple instances of a respective field effect transistor can be formed in each device region (100, 200, or 300). The photoresist layer can be subsequently removed, for example, by ashing.

At least one dielectric material such as undoped silicate glass can be deposited in the shallow trenches by a conformal deposition process such as a chemical vapor deposition process. A chemical mechanical planarization process can be performed to remove portions of the at least one dielectric material from above the pad layers. The remaining portions of the at least one dielectric material constitute shallow trench isolation structures 20. The pad layers can be subsequently removed, for example, by wet etch processes. For example, a wet etch employing hot phosphoric acid can be performed to remove the silicon nitride layer, and a wet etch process employing dilute hydrofluoric acid can be performed to remove the silicon oxide layer. Physically exposed surfaces of the shallow trench isolation structures 20 may be collaterally recessed during removal of the silicon oxide layer.

Generally, a shallow trench isolation structure 20 comprising a dielectric material can be formed in an upper region of the semiconductor material layer 10. The semiconductor material layer can have a doping of the first conductivity type, and the shallow trench isolation structure 20 can laterally surround each device region of the semiconductor material layer 10 such as the first device region 100, the second device region 200, and the third device region 300.

A first gate dielectric layer 152L having a thickness suitable for operation of a high voltage field effect transistor can be formed on all physically exposed surfaces of the semiconductor material layer 10, for example, by thermal oxidation of the physically exposed surface portions of the semiconductor material layer 10. If the semiconductor material layer 10 includes single crystalline silicon, the first gate dielectric layer can consist essentially of thermal silicon oxide. The thickness of the first gate dielectric layer 152L can be in a range from 6 nm to 30 nm, although lesser and greater thicknesses can also be employed.

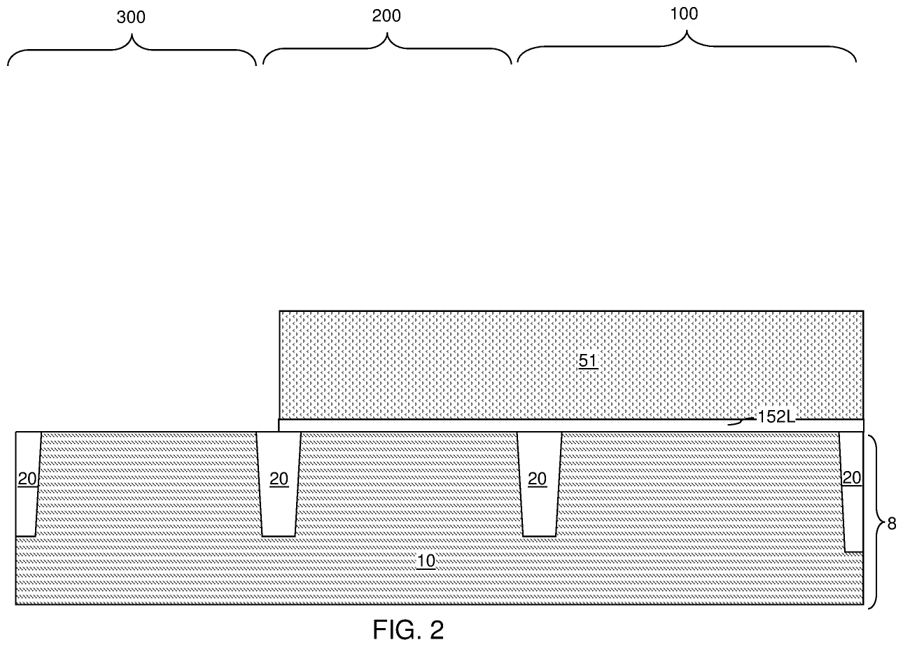

Referring to FIG. 2, a photoresist layer 51 can be applied over the exemplary structure, and can be lithographically patterned to cover the first device region 100 and the second device region 200 without covering the third device region 300. An isotropic etch process such as a wet etch process employing dilute hydrofluoric acid can be performed to remove the portion of the first gate dielectric layer 152L located in the third device region 300. The photoresist layer 51 can be subsequently removed, for example, by ashing.

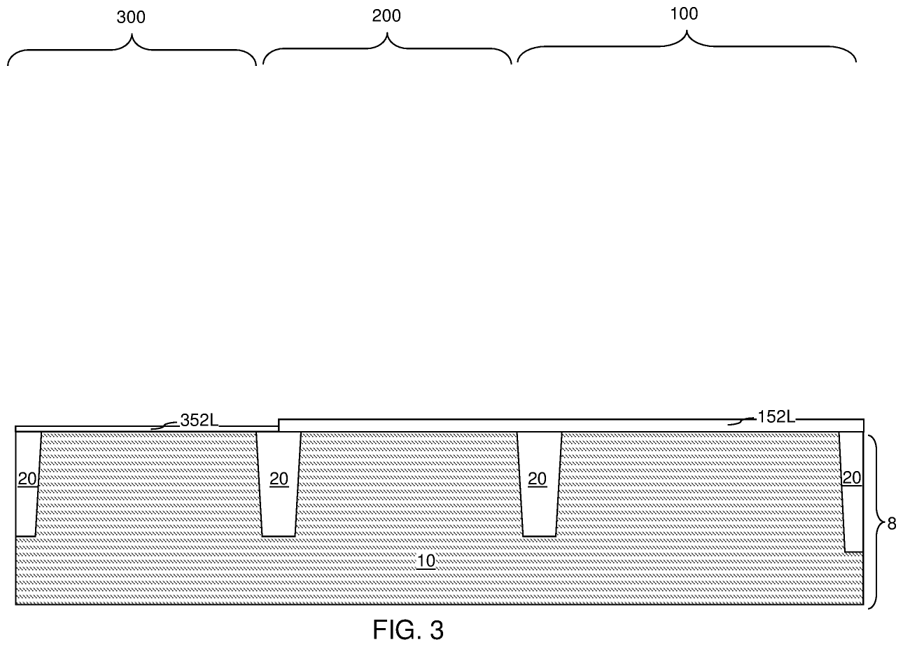

Referring to FIG. 3, a second gate dielectric layer 352L can be formed in the third device region 300. For example, a thermal oxidation process may be performed to convert a surface portion of the semiconductor material layer 10 in the third device region 300 into the second gate dielectric layer 352L. Optionally, a dielectric metal oxide layer may be deposited and may be incorporated into the second gate dielectric layer 352L. Any portion of the gate dielectric material that is formed on the first gate dielectric layer 152L during formation of the second gate dielectric layer 352L is incorporated into the first gate dielectric layer 152L. Generally, the first gate dielectric layer 152L has a thickness (such as a thickness in a range from 6 nm to 30 nm) that is suitable for operation of a high voltage field effect transistor, and the second gate dielectric layer 352L has a thickness that is suitable for operation of a low voltage field effect transistor. The second gate dielectric layer 352L is thinner than the first gate dielectric layer 152L. In an illustrative example, the second gate dielectric layer 352L can have a thickness in a range from 1 nm to 4 nm, although lesser and greater thicknesses may also be employed.

In an alternative embodiment, the second gate dielectric layer 352L is formed first in the first, second and third device regions (100, 200, 300), followed by forming a mask over the second gate dielectric layer 352L in the third device region 300 and further oxidizing the exposed semiconductor material layer 10 in the first and second device regions (100, 200) to increase the thickness of the second gate dielectric layer 352L exposed in the first and second device regions (100, 200) to form the first gate dielectric layer 152L. Thus, the gate dielectric thickness of the high voltage field effect transistor in the first device region 100 is greater than the gate dielectric thickness of the low voltage field effect transistor in the third device region 300.

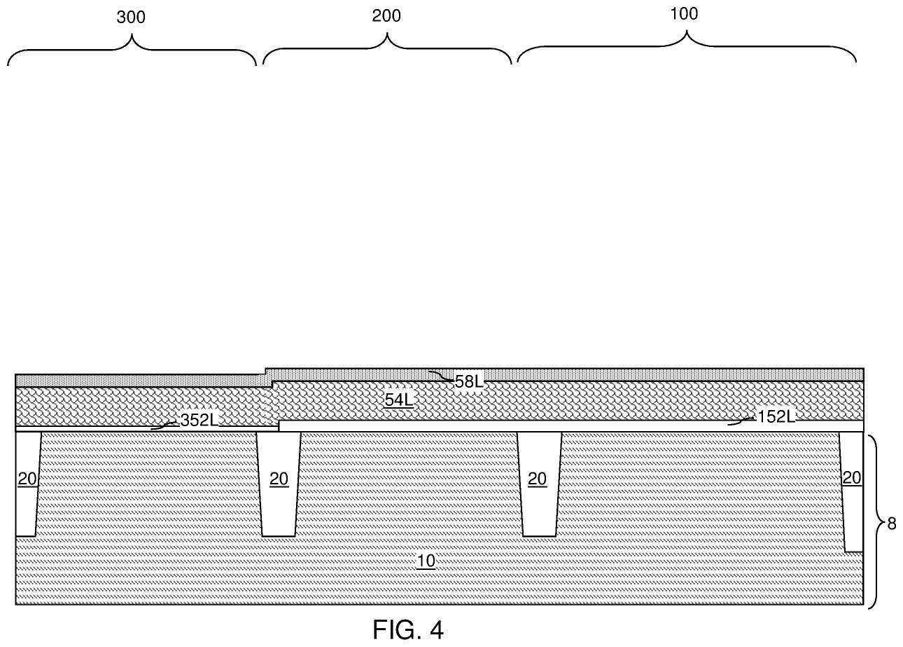

Referring to FIG. 4, at least one gate electrode material layer 54L and a gate cap dielectric layer 58L can be deposited over the first gate dielectric layer 152L and the second gate dielectric layer 352L. The at least one gate electrode material layer 54L includes one or more layers of an electrically conductive material that can be employed as a gate electrode material. In an illustrative embodiment, the at least one gate electrode material layer 54L can include a semiconductor gate electrode layer including a doped semiconductor material and a metallic gate electrode layer including a metallic gate electrode material. For example, the semiconductor gate electrode layer can include a doped polysilicon layer having a thickness in a range from 30 nm to 150 nm, and the metallic gate electrode layer can include a metallic material such as a transition metal or metal silicide and can have a thickness in a range from 50 nm to 150 nm, although lesser and greater thicknesses may also be employed. The gate cap dielectric layer 58L includes a gate cap dielectric material such as silicon nitride, and can have a thickness in a range from 30 nm to 100 nm, although lesser and greater thicknesses may also be employed.

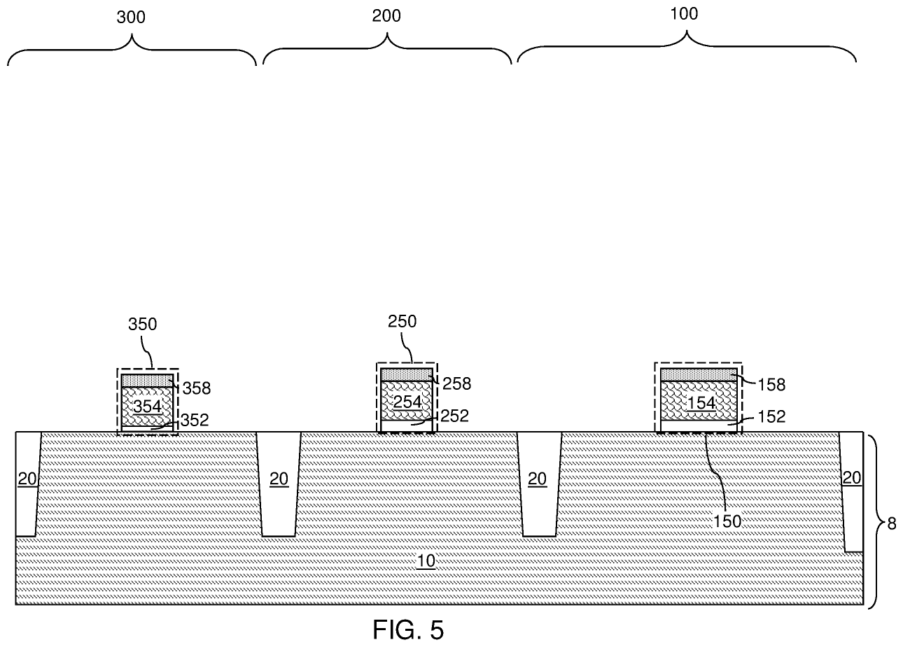

Referring to FIG. 5, a photoresist layer can be applied over the gate cap dielectric layer, and can be lithographically patterned to form gate patterns, i.e., patterns of gate electrodes to be subsequently formed. In one embodiment, the gate patterns can cover middle portions of the device regions such as a middle portion of the first device region 100, a middle portion of the second device region 200, and a middle portion of the third device region 300. An anisotropic etch process can be performed to transfer the gate patterns through the gate cap dielectric layer 58L, the at least one gate electrode layer 54L, the first gate dielectric layer 152L, and the second gate dielectric layer 352L. A terminal step of the anisotropic etch process can be selective to the semiconductor material of the semiconductor material layer 10 so that overetch into the semiconductor material layer 10 is minimized. The photoresist layer can be removed, for example, by ashing.

Each patterned portion of the gate cap dielectric layer 58L comprises a gate cap dielectric (158, 258, 358). The gate cap dielectrics (158, 258, 358) include a first gate cap dielectric 158 that is formed in the first device region 100, a second gate cap dielectric 258 that is formed in the second device region 200, and a third gate cap dielectric 358 that is formed in the third device region 300. Each patterned portion of the at least one gate electrode layer 54L comprises a gate electrode (154, 254, 354). The gate electrodes (154, 254, 354) include a first gate electrode 154 that is formed in the first device region 100, a second gate electrode 254 that is formed in the second device region 200, and a third gate electrode 354 that is formed in the third device region 300. In case the at least one gate electrode layer includes a semiconductor gate electrode layer and a metallic gate electrode layer, each gate electrode (154, 254, 354) can include a respective stack of a semiconductor gate electrode and a metallic gate electrode. A patterned portion of the first gate dielectric layer 152L formed in the first device region 100 includes a first gate dielectric 152, and a patterned portion of the first gate dielectric layer 152L formed in the second device region 200 includes a second gate dielectric 252. A patterned portion of the second gate dielectric layer 352L formed in the third device region 300 includes a third gate dielectric 352.

The contiguous set of material portions including the first gate dielectric 152, the first gate electrode 154, and the first gate cap dielectric 158 in the first device region 100 comprises a first gate stack structure 150. The contiguous set of material portions including the second gate dielectric 252, the second gate electrode 254, and the second gate cap dielectric 258 in the second device region 200 comprises a second gate stack structure 250. The contiguous set of material portions including the third gate dielectric 352, the third gate electrode 354, and the third gate cap dielectric 358 in the third device region 300 comprises a third gate stack structure 350. The lateral dimension between two edges of the first gate dielectric 152 that contact the semiconductor material layer 10 in the first device region 100 is the first gate length of the first gate stack structure 150, which can be in a range from 200 nm to 3,000 nm, although lesser and greater dimensions may also be employed. The lateral dimension between two edges of the second gate dielectric 252 that contact the semiconductor material layer 10 in the second device region 200 is the second gate length of the second gate stack structure 250, which can be in a range from 20 nm to 1,000 nm, although lesser and greater dimensions may also be employed. The lateral dimension between two edges of the third gate dielectric 352 that contact the semiconductor material layer 10 in the third device region 300 is the third gate length of the third gate stack structure 350, which can be in a range from 5 nm to 100 nm, although lesser and greater dimensions may also be employed. Thus, the gate length of the high voltage field effect transistor including the first gate stack structure 150 is longer than the gate length of the medium and low voltage field effect transistors including the respective second and third gate stack structures (250, 350).

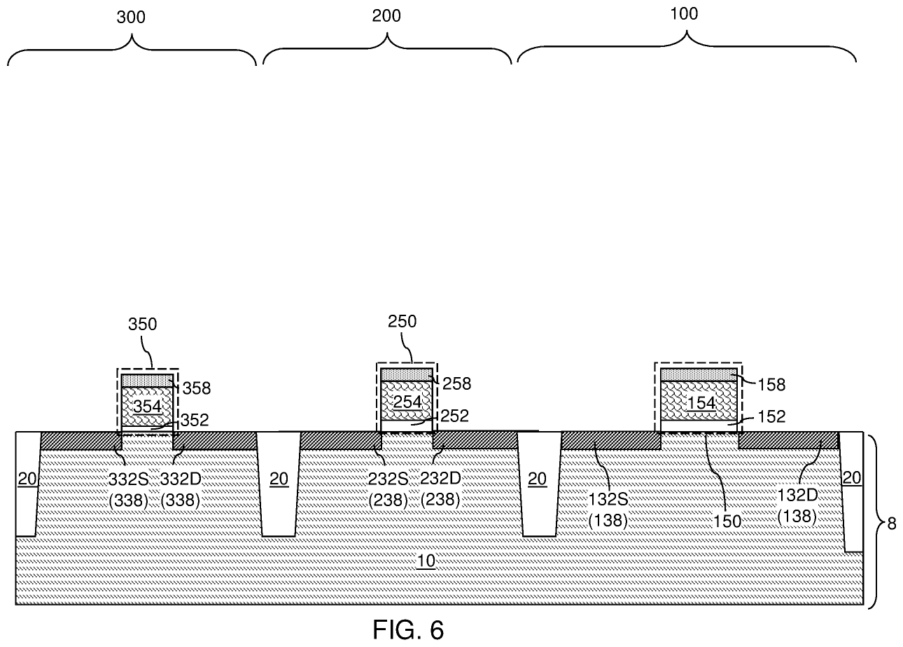

Referring to FIG. 6, doped semiconductor material portions having a doping of a second conductivity type can be formed within surface portions of the semiconductor material layer 10 that are not covered by the gate stack structures (150, 250, 350). Specifically, a relatively low dose ion implantation process can be performed to implant dopants of the second conductivity type into the surface portions of the semiconductor material layer 10. The second conductivity type is the opposite of the first conductivity type, which is the conductivity type of the semiconductor material layer 10 within the first device region 100, the second device region 200, and the third device region 300. For example, if the first conductivity type is p-type, the second conductivity type is n-type, and vice versa.

Lightly-doped source/drain regions (132S, 132D, 232S, 232D, 332S, 332D) are formed simultaneously by implanting electrical dopants of the second conductivity type. The lightly-doped source/drain regions (132S, 132D, 232S, 232D, 332S, 332D) are formed within the implanted portions of the semiconductor material layer 10. The lightly-doped source/drain regions (132S, 132D, 232S, 232D, 332S, 332D) comprise components of a respective source region or a respective drain region. The lightly-doped source/drain regions (132S, 132D, 232S, 232D, 332S, 332D) can include dopants of the second conductivity type at a first atomic concentration, which may be in a range from 1.0×10¹⁷/cm³ to 1.0×10¹⁹/cm³, such as from 2.0×10¹⁸/cm³ to 5.0×10¹⁸/cm³, although lesser and greater atomic concentrations may also be employed.

The lightly-doped source/drain regions (132S, 132D, 232S, 232D, 332S, 332D) include a first source region 132S and a first drain region 132D of a first (i.e., high voltage) field effect transistor to be formed in the first device region 100, a source extension region 232S and a drain extension region 232D of an optional second (i.e., medium voltage) field effect transistor to be formed in the second device region 200, and a source extension region 332S and a drain extension region 332D of a third (i.e., low voltage) field effect transistor to be formed in the third device region 300. The first source region, the first drain region, the source extension regions, and the drain extension regions include electrical dopants of the second conductivity type at the first atomic concentration.

The first source region 132S and the first drain region 132D are collectively referred to as first source/drain regions 138 of the first field effect transistor. The source extension region 232S and the drain extension region 232D of the second field effect transistor are formed within portions of the semiconductor material layer 10 that underlie peripheral portions of the second gate structure 250, and can contact a respective peripheral portion of a bottom surface of the second gate dielectric 252. The source extension region 232S and the drain extension region 232D of the second field effect transistor are portions of second source/drain regions 238 of the second field effect transistor. The source extension region 332S and the drain extension region 332D of the third field effect transistor are formed within portions of the semiconductor material layer 10 that underlie peripheral portions of the third gate structure 350, and can contact a respective peripheral portion of a bottom surface of the third gate dielectric 352. The source extension region 332S and the drain extension region 332D of the third field effect transistor are portions of third source/drain regions 338 of the third field effect transistor.

In one embodiment, each of the first source region 132S, the first drain region 132D, the source extension regions (232S, 332S), and the drain extension regions (232D, 332D) can have a respective planar bottom surface located at a first depth from a top surface of the semiconductor material layer 10. In other words, each of the first source region 132S, the first drain region 132D, the source extension regions (232S, 332S), and the drain extension regions (232D, 332D) can have the same height (i.e., thickness). The first depth can be in a range from 5 nm to 100 nm, such as from 10 nm to 50 nm, although lesser and greater depths may also be employed.

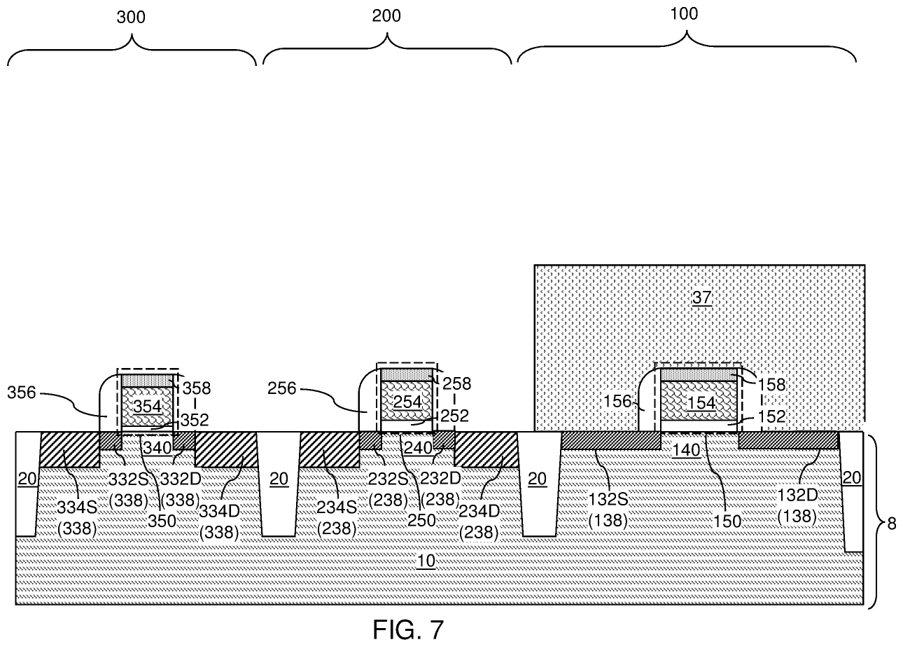

Referring to FIG. 7, at least one conformal dielectric material layer, including a dielectric material such as silicon oxide or silicon nitride can be deposited, for example, by a chemical vapor deposition process. The thickness of the at least one conformal dielectric material layer can be less than the lateral separation distance between the first gate stack structure 150 and each of the first source region 132S and the first drain region 132D. For example, the thickness of the at least one conformal dielectric material layer may be in a range from 10 nm to 300 nm, such as from 20 nm to 150 nm, although lesser and great thicknesses may also be employed.

The at least one conformal dielectric layer can be anisotropically etched by an anisotropic sidewall spacer etch process, such as a reactive ion etch process. Each remaining vertically-extending portion of the at least one conformal dielectric layer comprises a respective dielectric gate spacer (i.e., sidewall spacer) (156, 256, 356). A first dielectric gate spacer 156 is formed around the first gate stack structure 150 in the first device region 100, a second dielectric gate spacer 256 is formed around the second gate stack structure 250 in the second device region 200, and a third dielectric gate spacer 356 is formed around the third gate stack structure 350 in the third device region 300. The first dielectric gate spacer 156 can be formed directly on sidewalls of the first gate stack structure 150. The second dielectric gate spacer 256 can be formed directly on sidewalls of the second gate stack structure 250. The third dielectric gate spacer 356 can be formed directly on sidewalls of the third gate stack structure 350. The lateral thickness of each of the dielectric gate spacers (156, 256, 356) may be in a range from 10 nm to 300 nm, such as from 20 nm to 150 nm, although lesser and great thicknesses may also be employed.

The first source region 132S and the first drain region 132D are formed within respective areas that are laterally spaced from the first gate structure 150 by a lateral separation distance that is greater than the lateral thickness of the dielectric gate spacers (156, 256, 356). Thus, the first source region 132S and the first drain region 132D are laterally spaced outward from and do not overlap in the vertical direction with outer sidewalls of the first dielectric gate spacer 156. The second dielectric gate spacer 256 is formed on top surfaces of the source extension region 232S and the drain extension region 232D in the second device region 200. The source extension region 232S and the drain extension region 232D contact a bottom surface of and vertically overlap with the second dielectric gate spacer 256. The third dielectric gate spacer 356 is formed on top surfaces of the source extension region 332S and the drain extension region 332D in the third device region 300. The source extension region 332S and the drain extension region 332D contact a bottom surface of and vertically overlap with the third dielectric gate spacer 356.

A second patterned implantation mask layer 37 can be formed over the exemplary structure to mask the first device region 100 without masking the second device region 200 or the third device region 300. In one embodiment, the second patterned implantation mask layer 37 may comprise a patterned photoresist layer, which can be formed by applying and lithographically patterned over the exemplary structure.

Additional doped semiconductor material portions having a doping of the second conductivity type can be formed within surface portions of the semiconductor material layer 10 that are not covered by the second patterned implantation mask layer 37. Specifically, a relatively high dose ion implantation process can be performed to implant dopants of the second conductivity type into the surface portions of the semiconductor material layer 10 that are not covered by the second patterned implantation mask layer 37.

Heavily-doped source/drain regions (234S, 234D, 334S, 334D) are formed simultaneously by implanting electrical dopants of the second conductivity type through openings in the second patterned implantation mask layer 37. The heavily-doped source/drain regions (234S, 234D, 334S, 334D) are formed within the implanted portions of the semiconductor material layer 10. The heavily-doped source/drain regions (234S, 234D, 334S, 334D) comprise components of a respective source region or a respective drain region. The heavily-doped source/drain regions (234S, 234D, 334S, 334D) can include dopants of the second conductivity type at a second atomic concentration, which may be in a range from 1.0×10¹⁹/cm³ to 2.0×10²¹/cm³, such as from 2.0×10¹⁹/cm³ to 1.0×10²¹/cm³, although lesser and greater atomic concentrations may also be employed. The second atomic concentration can be greater than the first atomic concentration. In one embodiment, the ratio of the second atomic concentration to the first atomic concentration may be in a range from 2 to 200, such as from 10 to 50, although lesser and greater ratios may also be employed.

The heavily-doped source/drain regions (234S, 234D, 334S, 334D) include a deep source region 234S and a deep drain region 234D of the second field effect transistor that is formed in the second device region 200, and a deep source region 334S and a deep drain region 334D of the third field effect transistor that is formed in the third device region 300. The deep source regions (234S, 334S) and the deep drain regions (234D, 334D) include electrical dopants of the second conductivity type at the second atomic concentration. Implanted portions of the source extension regions (232S, 332S) and the drain extension regions (232D, 332D) are incorporated into a respective one of the deep source regions (234S, 334S) and the deep drain regions (234D, 334D).

In one embodiment, each of the deep source regions (234S, 334S) and the deep drain regions (234D, 334D) has a respective bottom surface located at a second depth from the top surface of the semiconductor material layer 10. The second depth is greater than the first depth. The second depth can be in a range from 20 nm to 600 nm, such as from 40 nm to 300 nm, although lesser and greater depths may also be employed.

In one embodiment, a vertical sidewall of the deep source region 234S of the second field effect transistor contacts the source extension region 232S of the second field effect transistor, contacts a channel region of the second field effect transistor (which is herein referred to as a second channel region 240), and can be vertically coincident with a first outer sidewall of the second dielectric gate spacer 256 (i.e., located within a same vertical plane as the first outer sidewall of the second dielectric gate spacer 256). In one embodiment, a vertical sidewall of the deep drain region 234D of the second field effect transistor contacts the drain extension region 232D of the second field effect transistor, contacts the second channel region 240 of the second field effect transistor, and can be vertically coincident with a second outer sidewall of the second dielectric gate spacer 256.

In one embodiment, a vertical sidewall of the deep source region 334S of the third field effect transistor contacts the source extension region 332S of the third field effect transistor, contacts a channel region of the third field effect transistor (which is herein referred to as a third channel region 340), and can be vertically coincident with a first outer sidewall of the third dielectric gate spacer 356 (i.e., located within a same vertical plane as the first outer sidewall of the third dielectric gate spacer 356). In one embodiment, a vertical sidewall of the deep drain region 334D of the third field effect transistor contacts the drain extension region 332D of the third field effect transistor, contacts the third channel region 340 of the third field effect transistor, and can be vertically coincident with a second outer sidewall of the third dielectric gate spacer 356. The second patterned implantation mask layer 37 can be subsequently removed, for example, by ashing.

The source/drain regions 138 of the first field effect transistor consist of only the first source region 132S and the first drain region 132D. The source/drain regions 238 of the second field effect transistor comprise a second source region (232S, 234S) and a second drain region (232D, 234D). The second source region (232S, 234S) includes the second source extension region 232S and the second deep source region 234S. The second drain region (232D, 234D) includes the second drain extension region 232D and the second deep drain region 234D. The source/drain regions 338 of the third field effect transistor comprise a third source region (332S, 334S) and a third drain region (332D, 334D). The third source region (332S, 334S) includes the third source extension region 332S and the third deep source region 334S. The third drain region (332D, 334D) includes the third drain extension region 332D and the third deep drain region 334D.

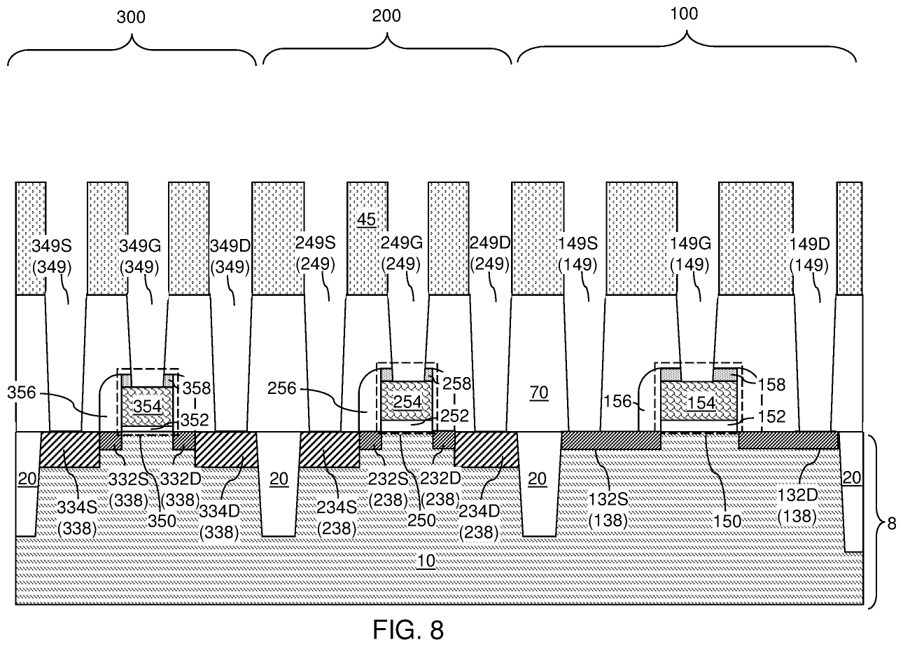

Referring to FIG. 8, a contact-level dielectric layer 70 can be formed over the gate stack structures (150, 250, 350) and dielectric gate spacers (156, 256, 356). The contact-level dielectric layer 70 can include a self-planarizing dielectric material such as flowable oxide (FOX) or a planarizable dielectric material such as undoped silicate glass or a doped silicate glass. In case the contact-level dielectric layer 70 includes undoped silicate glass or a doped silicate glass, a top surface of the contact-level dielectric layer 70 can be planarized by performing a chemical mechanical planarization process. The top surface of the contact-level dielectric layer 70 may be vertically spaced above the horizontal plane including the bottom surfaces of the gate cap dielectrics (158, 258, 358) by a vertical distance in a range from 100 nm to 1,000 nm, such as from 200 nm to 500 nm, although lesser and greater vertical spacings may also be employed.

A photoresist layer 45 can be applied over the contact-level dielectric layer 70, and can be lithographically patterned to form discrete openings in areas that overlie the first source region 132S, the first drain region 132D, and the first gate electrode 154 of the first field effect transistor, the deep source region 234S, the deep drain region 234D, and the second gate electrode 254 of the second field effect transistor, and the deep source region 334S, the deep drain region 334D, and the third gate electrode 354 of the third field effect transistor.

An anisotropic etch process can be performed to transfer the pattern of the openings in the photoresist layer 45 through the contact-level dielectric layer 70 and the gate cap dielectrics (158, 258, 358). Contact via cavities (149, 249, 349) are formed through the contact-level dielectric layer 70 and the gate cap dielectrics (158, 258, 358). Top surfaces of the first source region 132S, the first drain region 132D, and the first gate electrode 154 of the first field effect transistor, the deep source region 234S, the deep drain region 234D, and the second gate electrode 254 of the second field effect transistor, and the deep source region 334S, the deep drain region 334D, and the third gate electrode 354 of the third field effect transistor are physically exposed underneath the contact via cavities (149, 249, 349).

The contact via cavities (149, 249, 349) include first contact via cavities 149 which overlie physically exposed surfaces of the first field effect transistor, second contact via cavities 249 which overlie physically exposed surfaces of the second field effect transistor, and third contact via cavities 349 which overlie physically exposed surfaces of the third field effect transistor. The first contact via cavities 149 include a first source-side contact via cavity 149S that overlies the first source region 132S, a first drain-side contact via cavity 149D that overlies the first drain region 132D, and a first gate-side contact via cavity 149G that overlies the first gate electrode 154. The second contact via cavities 249 include a second source-side contact via cavity 249S that overlies the second source region 232S, a second drain-side contact via cavity 249D that overlies the second drain region 232D, and a second gate-side contact via cavity 249G that overlies the second gate electrode 254. The third contact via cavities 349 include a third source-side contact via cavity 349S that overlies the third source region 332S, a third drain-side contact via cavity 349D that overlies the third drain region 332D, and a third gate-side contact via cavity 349G that overlies the third gate electrode 354.

Each of the contact via cavities (149, 249, 349) can include a respective straight sidewall that vertically extends from a top surface of the contact-level dielectric layer 70 to a top surface of a respective one of the first source region 132S, the first drain region 132D, the first gate electrode 154, the deep source region 234S of the second field effect transistor, the deep drain region 234D of the second field effect transistor, and the second gate electrode 254 of the second field effect transistor, and the deep source region 334S of the third field effect transistor, the deep drain region 334D of the third field effect transistor, and the third gate electrode 354. The photoresist layer 45 can be subsequently removed, for example, by ashing.

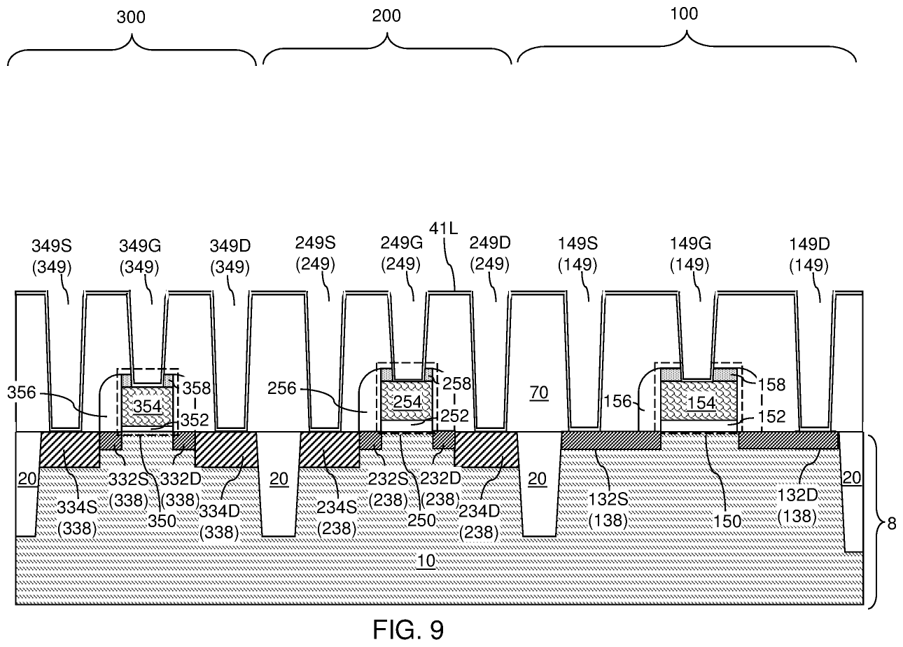

Referring to FIG. 9, a continuous dielectric liner 41L can be formed at peripheral portions of the contact via cavities (149, 249, 349) and above the contact-level dielectric layer 70 as a continuous material layer without openings therethrough. In one embodiment, the continuous dielectric liner 41L can be formed by a conformal deposition process such as a chemical vapor deposition process or an atomic layer deposition process.

The continuous dielectric liner 41L can include a single dielectric material layer or a stack of a plurality of dielectric material layers. In one embodiment, the continuous dielectric liner 41L can include a dielectric metal oxide layer consisting essentially of a dielectric metal oxide. As used herein, a dielectric metal oxide refers to a dielectric material that includes at least one metallic element and at least oxygen. The dielectric metal oxide may consist essentially of the at least one metallic element and oxygen, or may consist essentially of the at least one metallic element, oxygen, and at least one non-metallic element such as nitrogen. In one embodiment, the continuous dielectric liner 41L can include a dielectric metal oxide having a dielectric constant greater than 7.9, i.e., having a dielectric constant greater than the dielectric constant of silicon nitride.

Non-limiting examples of dielectric metal oxides include titanium oxide (TiO₂), aluminum oxide (Al₂O₃), hafnium oxide (HfO₂), lanthanum oxide (LaO₂), yttrium oxide (Y₂O₃), tantalum oxide (Ta₂O₅), silicates thereof, nitrogen-doped compounds thereof, alloys thereof, and stacks thereof. The dielectric metal oxide layer can be deposited, for example, by chemical vapor deposition (CVD), atomic layer deposition (ALD), pulsed laser deposition (PLD), liquid source misted chemical deposition, or a combination thereof. The thickness of the dielectric metal oxide layer can be in a range from 0.5 nm to 3 nm, although lesser and greater thicknesses can also be employed. The dielectric metal oxide layer can subsequently function as a dielectric material portion that blocks leakage of stored electrical charges to control gate electrodes. In one embodiment, the continuous dielectric liner 41L includes, and/or consists essentially of, titanium oxide. In one embodiment, the continuous dielectric liner 41L can include multiple dielectric metal oxide layers having different material compositions.

Alternatively or additionally, the continuous dielectric liner 41L can include a dielectric semiconductor compound such as silicon oxide, silicon oxynitride, silicon nitride, or a combination thereof. In one embodiment, the continuous dielectric liner 41L can include silicon oxide. In this case, the dielectric semiconductor compound of the continuous dielectric liner 41L can be formed by a conformal deposition method such as low pressure chemical vapor deposition, atomic layer deposition, or a combination thereof. The thickness of the dielectric semiconductor compound can be in a range from 0.5 nm to 3 nm, although lesser and greater thicknesses can also be employed. Generally, the thickness of the continuous dielectric liner 41L may be in a range from 0.5 nm to 5 nm, such as from 1.0 nm to 3 nm and/or from 1.2 nm to 2.0 nm, although lesser and greater thicknesses may also be employed.

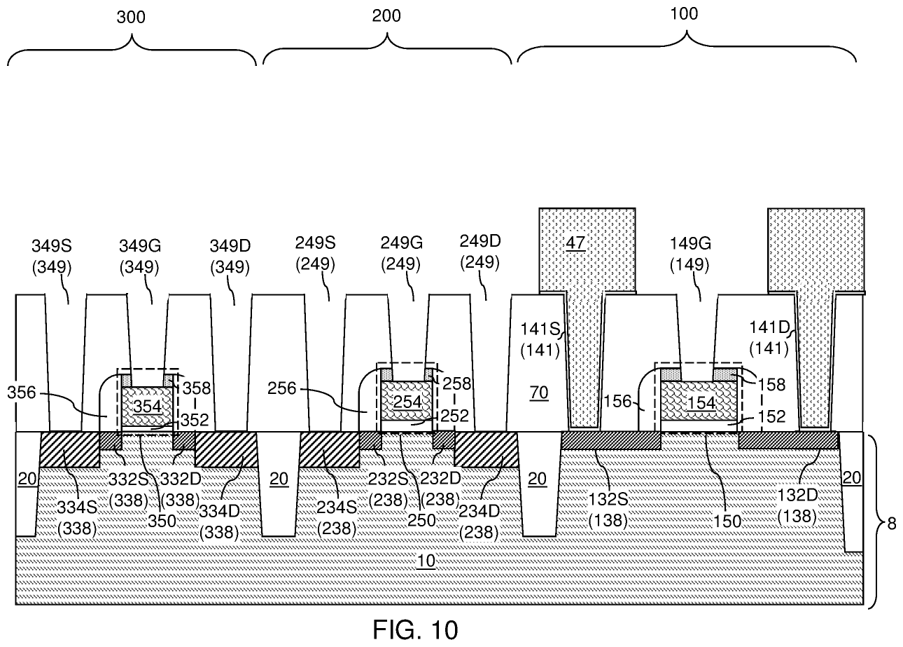

Referring to FIG. 10, a photoresist layer 47 can be applied over the continuous dielectric layer 41L, and can be lithographically patterned to cover the region of the first source-side contact via cavity 149S that overlies the first source region 132S, and to cover the region of the first drain-side contact via cavity 149D that overlies the first drain region 132D. The photoresist layer 47 can be removed from above the areas of the second contact via cavities 249 in the second device region 200, the third contact via cavities 349 in the third device region 300, and the first gate-side contact via cavity 149G in the first deice region 100.

An etch process can be performed to remove unmasked portions of the continuous dielectric liner 41L. The etch process may include an isotropic etch process (such as a wet etch process) or an anisotropic etch process (such as a reactive ion etch process). Remaining portions of the continuous dielectric liner 41L include a source-side dielectric liner 141S that is formed within and around the first source-side contact via cavity 149S, and a drain-side dielectric liner 141D that is formed within and around the first drain-side contact via cavity 149D. The photoresist layer 47 can be subsequently removed, for example, by ashing.

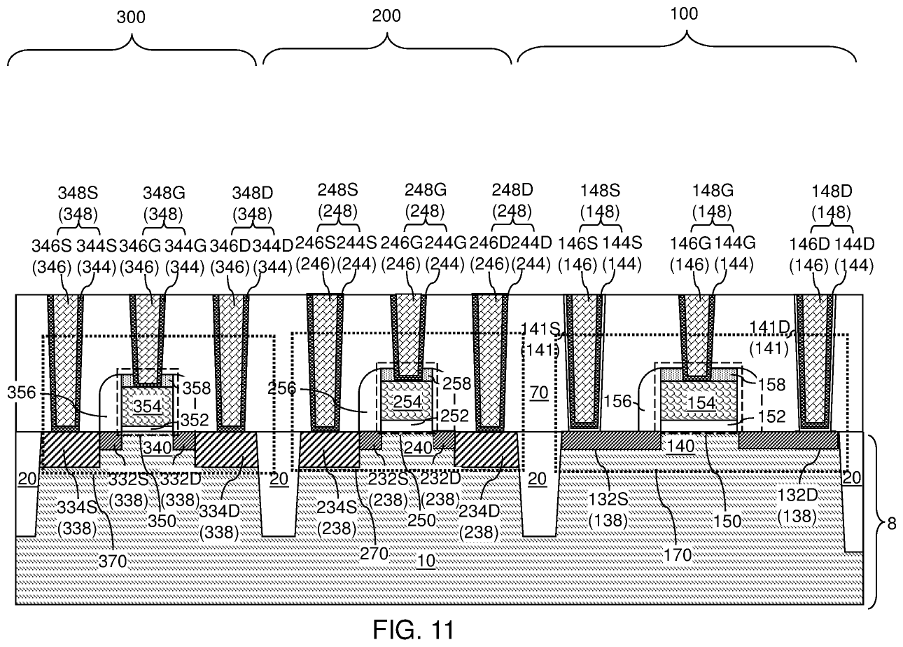

Referring to FIG. 11, at least one conductive material can be deposited in the via cavities (149, 249, 349) to form various contact via structures (148, 248, 348). For example, a metallic liner (such as a conductive metal nitride liner including TiN, TaN, or WN) and a metallic fill material (such as W, Ti, Co, Cu, Ru, or Al) may be sequentially deposited in the via cavities (149, 249, 349). Excess portions of the dielectric liners (141S, 141D), the metallic liner, and the metallic fill material can be removed from above the horizontal plane including the top surface of the contact-level dielectric layer 70 by a planarization process, such as chemical mechanical planarization or a recess etch. Each contiguous set of remaining conductive material portions constitutes a contact via structure (148, 248, 348). For example, the contact via structures (148, 248, 348) can include first contact via structures 148 that are formed in the first device region 100, second contact via structures 248 that are formed in the second device region 200, and third contact via structures 348 that are formed in the third device region 300.

The first contact via structures 148 comprise a first source contact via structure 148S that is embedded within (i.e., surrounded on the bottom and sides but not the top by) the source-side dielectric liner 141S, a first drain contact via structure 148D that is embedded within (i.e., surrounded on the bottom and sides but not the top by) the drain-side dielectric liner 141D, and a first gate contact via structure 148G that contacts the first gate electrode 154. Each of the first contact via structures 148 includes a respective first metallic liner 144 and a respective first metallic fill material portion 146. The first source contact via structure 148S can include a first source-side metallic liner 144S and a first source-side metallic fill material portion 146S. The first drain contact via structure 148D can include a first drain-side metallic liner 144D and a first drain-side metallic fill material portion 146D. The first gate contact via structure 148G can include a first gate-side metallic liner 144G and a first gate-side metallic fill material portion 146G. Thus, the first (i.e., high voltage) field effect transistor 170 includes metal-insulator-semiconductor (“MIS”) source and drain contacts comprising the first source and drain contact via structure (148S, 148D) (i.e., the “metal” vias), the source and drain side dielectric liners (141S, 141D) (i.e., the “insulator”) and the source and drain regions (132S, 132D) (i.e., the “semiconductor”).

The second contact via structures 248 comprise a second source contact via structure 248S that contacts the deep source region 234S of the second field effect transistor, a second drain contact via structure 248D that contacts the deep drain region 234D of the second field effect transistor, and a second gate contact via structure 248G that contacts the second gate electrode 254. Each of the second contact via structures 248 includes a respective second metallic liner 244 and a respective second metallic fill material portion 246. The second source contact via structure 248S can include a second source-side metallic liner 244S and a second source-side metallic fill material portion 246S. The second drain contact via structure 248D can include a second drain-side metallic liner 244D and a second drain-side metallic fill material portion 246D. The second gate contact via structure 248G can include a second gate-side metallic liner 244G and a second gate-side metallic fill material portion 246G.

The third contact via structures 348 comprise a third source contact via structure 348S that contacts the deep source region 334S of the third field effect transistor, a third drain contact via structure 348D that contacts the deep drain region 334D of the third field effect transistor, and a third gate contact via structure 348G that contacts the third gate electrode 354. Each of the third contact via structures 348 includes a respective third metallic liner 344 and a respective third metallic fill material portion 346. The third source contact via structure 348S can include a third source-side metallic liner 344S and a third source-side metallic fill material portion 346S. The third drain contact via structure 348D can include a third drain-side metallic liner 344D and a third drain-side metallic fill material portion 346D. The third gate contact via structure 348G can include a third gate-side metallic liner 344G and a third gate-side metallic fill material portion 346G. Thus, the second and third (i.e., medium and low voltage) field effect transistors (270, 370) include metal-semiconductor source and drain contacts that lack an insulating material between the electrically conductive contact via structures and the semiconductor source and drain regions.

In one embodiment, the entirety of a portion of the first source region 132S in contact with the source-side dielectric liner 141S includes electrical dopants of the second conductivity type at the first atomic concentration, and the entirety of a portion of the deep source regions (234S, 334S) in contact with the respective second and third source contact via structures (248S, 348S) include electrical dopants of the second conductivity type at the second atomic concentration greater than the first atomic concentration. The entirety of a portion of the first drain region 132D in contact with the drain-side dielectric liner 141D includes electrical dopants of the second conductivity type at the first atomic concentration, and the entirety of a portion of the deep drain regions (234D, 334D) in contact with the respective second and third drain contact via structures (248D, 348D) include electrical dopants of the second conductivity type at the second atomic concentration greater than the first atomic concentration.

In one embodiment, the contact-level dielectric layer 70 overlies the semiconductor material layer 10, and laterally surrounds the first source contact via structure 148S and the first drain contact via structure 148D. The source-side dielectric liner 141S and the drain-side dielectric liner 141D have a respective annular top surface within a horizontal plane including the top surface of the contact-level dielectric layer 70.

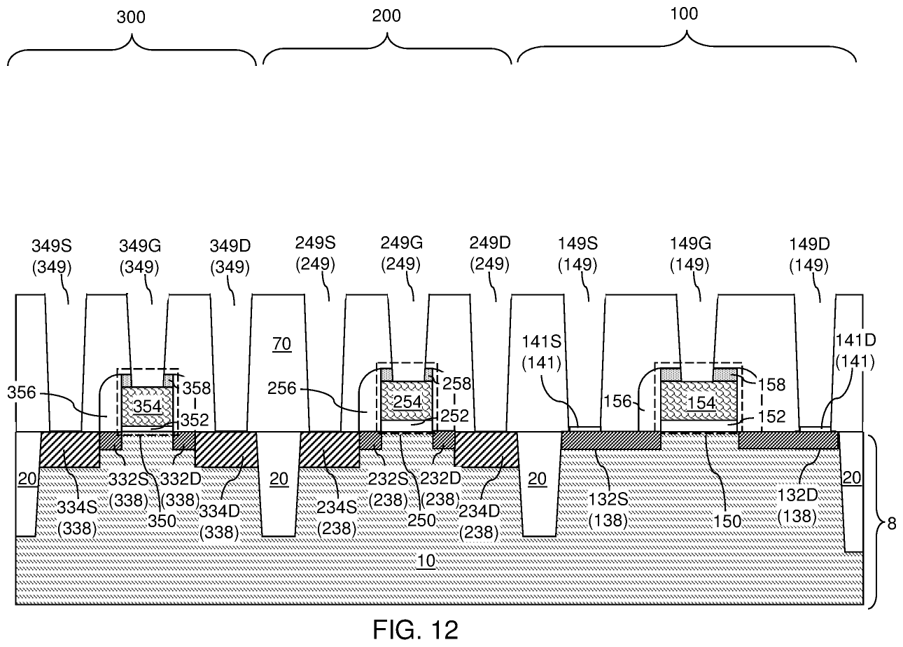

Referring to FIG. 12, an alternative embodiment of the exemplary structure is illustrated. The alterative embodiment of the exemplary structure can be derived from the exemplary structure of FIG. 8 after removing the photoresist layer 45. Instead of depositing the dielectric liner layer 41L, an oxidation and/or a nitridation process can be performed to oxidize and/or to nitride surface portions of the semiconductor source/drain regions (138, 238, 338). Specifically, semiconductor surface portions of the first source region 132S, the first drain region 132D of the first field effect transistor 170, the deep source region 234S and the deep drain region 234D of the second field effect transistor 270, and the deep source region 334D and the deep drain region 334D of the third field effect transistor 370 are converted to a semiconductor oxide and/or nitride dielectric material to form various dielectric liners including a dielectric compound of the semiconductor material of the semiconductor material layer 10. The dielectric material may comprise silicon oxide, silicon nitride or silicon oxynitride.

A photoresist layer (not shown) can be applied over the device, and can be lithographically patterned to cover the region of the first source-side contact via cavity 149S that overlies the first source region 132S, and to cover the region of the first drain-side contact via cavity 149D that overlies the first drain region 132D. The photoresist layer can be removed from above the areas of the second contact via cavities 249 in the second device region 200, the third contact via cavities 349 in the third device region 300, and the first gate-side contact via cavity 149G in the first device region 100.

An etch process can be performed to remove unmasked dielectric liners. The etch process may include an isotropic etch process (such as a wet etch process) or an anisotropic etch process (such as a reactive ion etch process). The photoresist layer can be subsequently removed, for example, by ashing. Remaining dielectric liners include a source-side dielectric liner 141S that is located at the bottom of the first source-side contact via cavity 149S, and a drain-side dielectric liner 141D that is located at the bottom of the first drain-side contact via cavity 149D.

Generally, the exposed semiconductor surface portions of the first source region 132S, the first drain region 132D, the deep source regions (234S, 334S), and the deep drain regions (234D, 334D) can be oxidized and/or nitrided in the contact via cavities (149, 249, 349). Oxidized or nitrided surface portions of the first source region 132S and the first drain region 132D comprise the source-side dielectric liner 141S and the drain-side dielectric liner 141D, respectively. The oxidized or nitrided surface portions of the deep source regions (234S, 334S) and the deep drain regions (234D, 334D) can be removed to physically expose surfaces of the deep source regions (234S, 334S) and the deep drain regions (234D, 334D).

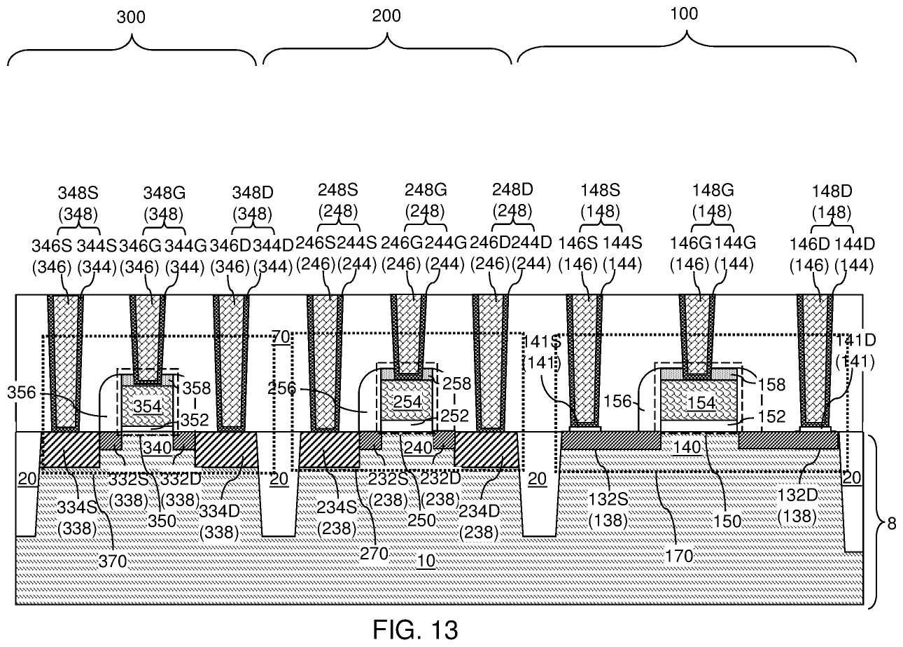

Referring to FIG. 13, is the processing steps of FIG. 11 can be performed to form contact via structures (148, 248, 348) in the various contact via cavities (149, 249, 349). Generally, the contact via structures (148, 248, 348) comprise at least one conductive material in remaining volumes of the contact via cavities (149, 249, 349). The contact-level dielectric layer 70 overlies the semiconductor material layer 10, and laterally surrounds, and contacts sidewalls of, the first source contact via structure 148S and the first drain contact via structure 148D. In this case, the source-side dielectric liner 141S and the drain-side dielectric liner 141D are planar dielectric liners having a respective shape of a plate having a uniform thickness between a top surface and a bottom surface.

Without being limited to a particular theory, it is believed that the metal-insulator-semiconductor contact structures provide a lower resistance with lightly (i.e., lower) doped source and drain regions of the first (i.e., high voltage) field effect transistor 170 than metal-semiconductor contact structures. In contrast, the metal-semiconductor contact structures can provide a lower resistance with heavily (i.e., higher) doped source and drain regions of the second (i.e., medium voltage) and third (i.e., low voltage) field effect transistors (270, 370). Thus, the contact resistance of all transistors is optimized by using the MIS contact structures in the high voltage field effect transistor 170 having lightly doped source and drain regions, while using metal-semiconductor contact structures in the medium and low voltage field effect transistors (270, 370) having heavily doped source and drain regions.

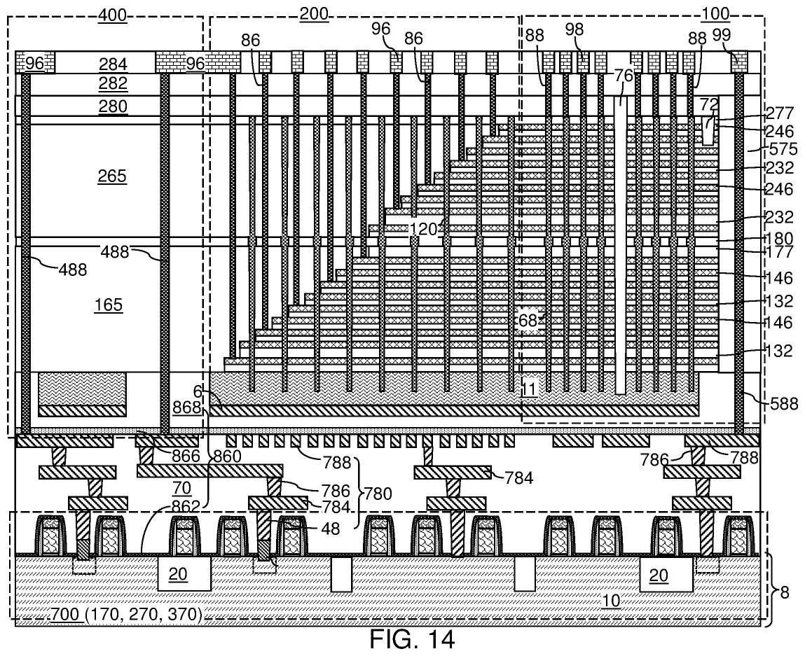

Referring to FIG. 14, the exemplary structure is illustrated after formation of a three-dimensional NAND memory array over the above described field effect transistors (170, 270, 370) located in the peripheral device region 700. The various field effect transistors on the semiconductor substrate 8 can include multiple instances of transistors described above. The field effect transistors (170, 270, 370) may be located in the peripheral (i.e., driver) circuit that controls the operation of the three-dimensional NAND memory array (e.g., as part of bit line and/or word line driver circuits). Alternatively, the field effect transistors (170, 270, 370) may be located in any other suitable logic or memory device.

Additional dielectric material layers can be formed over the exemplary structure. Lower-level dielectric material layers 860 can include, for example, optional dielectric (e.g., silicon nitride) liners 862, contact-level dielectric layer 70, a dielectric diffusion barrier layer 866 (such as a silicon nitride layer) that overlies the contact-level dielectric layer 70, and at least one second dielectric layer 868 that overlies the dielectric diffusion barrier layer 866.

Lower-level metal interconnect structures 780 can be formed within lower-level dielectric material layers 860 level by level. The lower-level metal interconnect structures 780 can include the various contact via structures 48 (which correspond to the contact structures 148, 248 and 348), various intermediate-level metal line structures 784, various metal via structures 786, and various top-level metal line structures 788. The dielectric diffusion barrier layer 866 and the at least one second dielectric layer 868 can be formed over the lower-level metal interconnect structures 780.

An optional layer of a metallic material and a layer of a semiconductor material can be deposited over, or within patterned recesses of, the at least one second dielectric material layer 868, and is lithographically patterned to provide an optional conductive plate layer 6 and source-level material layers 11. At least one alternating stack of insulating layers (132, 232) and spacer material layers can be formed and patterned to form stepped surfaces in a staircase region 200. A memory array region 100, in which each of the at least one alternating stack includes each layer therein, is provided adjacent to the staircase region. The spacer material layers can be formed as electrically conductive layers (146, 246), or can be formed as sacrificial material layers and can be subsequently replaced with electrically conductive layers (146, 246). For example, the at least one alternating stack can include a first alternating stack of first insulating layers 132 and first electrically conductive layers 146 and a second alternating stack of second insulating layers 232 and second electrically conductive layers 246. Retro-stepped dielectric material portions (165, 265) can be formed over the stepped surfaces. For example, a first retro-stepped dielectric material portion 165 can be formed over the first stepped surfaces of the first alternating stack (132, 146), and a second retro-stepped dielectric material portion 265 can be formed over the second stepped surfaces of the second alternating stack (232, 246). Intermediate dielectric material layers can be formed as needed. For example, the intermediate dielectric material layers can include a first insulating cap layer 177, an inter-tier dielectric layer 180, and a second insulating cap layer 277. Drain-select-level isolation structures 72 can be formed as needed.

Memory openings are formed through each layer in the at least one alternating stack (132, 146, 232, 246) in the memory array region 100, and are filled within memory opening fill structures 68. Each memory opening fill structure 68 includes a memory stack structure. Each memory stack structure can include a memory film and a vertical semiconductor channel laterally surrounded by the memory film. For example, each memory film can include a blocking dielectric, a charge storage layer, and a tunneling dielectric. Support openings in the staircase region 200 are filled with support pillar structures 120 which have the same composition and structure as the memory opening fill structures 68 or which may comprise dielectric (e.g., silicon oxide) pillars. Backside trenches can be formed through the at least one alternating stack (132, 146, 232, 246) to divide the at least one alternating stack (132, 146, 232, 246) into multiple memory blocks that are laterally spaced apart and electrically isolated among one another. A dielectric wall structure 76 can be formed within each backside trench. Dielectric pillar structures 575 can be optionally formed in the memory array region 100.

Various contact-level dielectric layers (280, 282) can be formed over the at least one alternating stack (132, 146, 232, 246). The various contact-level dielectric layers (280, 282) can include a first contact-level dielectric layer 280 and a second contact-level dielectric layer 282. Various upper-level contact via structures can be formed through the contact-level dielectric layers (280, 282) and underlying dielectric material portions. The upper-level contact via structures can include staircase region contact via structures 86 that contact a respective one of the first and second electrically conductive layers (146, 246), drain contact via structures 88 that contact a respective drain region (not expressly shown) at an upper end of an underlying memory stack structure, through-memory-level peripheral contact via structures 488 that contact a respective one of the lower-level metal interconnect structures 780 in a peripheral contact region 400, and through-memory-level array-region contact via structures 588 that extend through a respective dielectric pillar structures 575 and contact a respective one of the lower-level metal interconnect structures 780 in the memory array region 100.

A line-level dielectric layer 284 can be formed over the contact-level dielectric layers (280, 282). Upper metal line structures (96, 98, 99) can be formed in the line-level dielectric layer 284. The upper metal liner structures (96, 98, 99) can include peripheral interconnection line structures 96 that contact at least one of the staircase region contact via structures 86 and the through-memory-level peripheral contact via structures 488, bit lines 98 that contact a respective subset of the drain contact via structures 88, and array-region interconnection line structures 99 that contact a respective one of the through-memory-level array-region contact via structures 588.

Referring to all drawings and according to various embodiments of the present disclosure, a semiconductor structure includes a high voltage field effect transistor 170 having metal-insulator-semiconductor active region contact structures and a low voltage field effect transistor 370 having metal-semiconductor active region contact structures, and at least one of a smaller gate dielectric thickness or a smaller gate length than the high voltage field effect transistor, as described above.

In one embodiment, the high voltage field effect transistor 170 comprises a first field effect transistor including a first channel region 140 having a doping of a first conductivity type and comprising a first portion of a semiconductor material layer 10 (which underlies the first gate dielectric 152), a first gate dielectric 152 overlying a middle portion of the first channel region, a first gate electrode 154 overlying the first gate dielectric 152, a first source region 132S and a first drain region 132D having a doping of a second conductivity type that is an opposite of the first conductivity type, a first source contact via structure 148S overlying the first source region 132S and vertically spaced from the first source region 132S by a source-side dielectric liner 141S, and a first drain contact via structure 148D overlying the first drain region 132D and vertically spaced from the first drain region 132D by a drain-side dielectric liner 141D.

The low voltage field effect transistor 370 comprises second field effect transistor including a second channel region 340 having a doping of the first conductivity type and comprising a second portion of the semiconductor material layer 10, a second gate dielectric 352 overlying a middle portion of the second channel region, a second gate electrode 354 overlying the second gate dielectric 352, a second source region (332S, 334S) including a source extension region 332S and a deep source region 334S, a second drain region (332D, 334D) including a drain extension region 332D and a deep drain region 334D, a second source contact via structure 348S contacting a top surface of the deep source region 334S, and a second drain contact via structure 348D contacting a top surface of the deep drain region 334D.

In one embodiment, the contact via structures (148, 248, 348) comprise a first source contact via structure 148S overlying the first source region 132S and vertically spaced from the first source region 132S by the source-side dielectric liner 141S, a first drain contact via structure 148D overlying the first drain region 132D and vertically spaced from the first drain region 132D by a drain-side dielectric liner 141D, a second source contact via structure 348S contacting a top surface of the deep source region 334S, and a second drain contact via structure 348D contacting a top surface of the deep drain region 334D.

In one embodiment, the source extension region 332S of the second field effect transistor is not in direct contact with the second source contact via structure 348S; and the drain extension region 332D of the second field effect transistor is not in direct contact with the second drain contact via structure 348D.

In one embodiment, the entirety of a bottom surface of the first source contact via structure 148S is located within the area defined by a periphery of a top surface of the first source region 132S; and the entirety of a bottom surface of the first drain contact via structure 148D is located within an area defined by a periphery of a top surface of the first drain region 132D. In one embodiment, the entirety of an interface between the second source contact via structure 348S and the deep source region 334S is located within an area defined by a periphery of a top surface of the deep source region 334S; and the entirety of an interface between the second drain contact via structure 348D and the deep drain region 334D is located within an area defined by a periphery of a top surface of the deep drain region 334D.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. All of the publications, patent applications and patents cited herein are incorporated herein by reference in their entirety.

What is claimed is:

1. A semiconductor structure, comprising:
a high voltage field effect transistor having metal-insulator-semiconductor active region contact structures; and
a low voltage field effect transistor having metal-semiconductor active region contact structures, and at least one of (i) a smaller gate dielectric thickness or (ii) a smaller gate length than the high voltage field effect transistor.

2. The semiconductor structure of claim 1, wherein:
the high voltage field effect transistor comprises a first field effect transistor including a first channel region having a doping of a first conductivity type and comprising a first portion of a semiconductor material layer, a first gate dielectric overlying a middle portion of the first channel region, a first gate electrode overlying the first gate dielectric, a first source region and a first drain region having a doping of a second conductivity type that is an opposite of the first conductivity type, a first source contact via structure overlying the first source region and vertically spaced from the first source region by a source-side dielectric liner, and a first drain contact via structure overlying the first drain region and vertically spaced from the first drain region by a drain-side dielectric liner; and
the low voltage field effect transistor comprises a second field effect transistor including a second channel region having a doping of the first conductivity type and comprising a second portion of the semiconductor material layer, a second gate dielectric overlying a middle portion of the second channel region, a second gate electrode overlying the second gate dielectric, a second source region including a source extension region and a deep source region, a second drain region including a drain extension region and a deep drain region, a second source contact via structure contacting a top surface of the deep source region, and a second drain contact via structure contacting a top surface of the deep drain region.

3. The semiconductor structure of claim 2, wherein:
the first source region, the first drain region, the source extension region, and the drain extension region include electrical dopants of the second conductivity type at a first atomic concentration; and
the deep source region and the deep drain region include electrical dopants of the second conductivity type at a second atomic concentration that is greater than the first atomic concentration.

4. The semiconductor structure of claim 3, wherein:
an entirety of a portion of the first source region in contact with the source-side dielectric liner includes electrical dopants of the second conductivity type at the first atomic concentration; and
an entirety of a portion of the deep source region in contact with the second source contact via structure includes electrical dopants of the second conductivity type at the second atomic concentration.

5. The semiconductor structure of claim 3, wherein:
the source extension region is not in direct contact with the second source contact via structure; and
the drain extension region is not in direct contact with the second drain contact via structure.

6. The semiconductor structure of claim 2, wherein:
each of the first source region, the first drain region, the source extension region, and the drain extension region has a respective planar bottom surface located at a first depth from a top surface of the semiconductor material layer; and
each of the deep source region and the deep drain region has a respective bottom surface located at a second depth from the top surface of the semiconductor material layer, the second depth being greater than the first depth.

7. The semiconductor structure of claim 2, wherein:
each of the source extension region and the drain extension region contacts a peripheral portion of a bottom surface of the second gate dielectric; and
each of the first source region and the first drain region is laterally spaced from and does not contact the first gate dielectric.

8. The semiconductor structure of claim 2, further comprising:
a first dielectric gate spacer laterally surrounding the first gate electrode; and
a second dielectric gate spacer laterally surrounding the second gate electrode, wherein the source extension region and the drain extension region contact a bottom surface of the second dielectric gate spacer.

9. The semiconductor structure of claim 8, wherein:
a vertical sidewall of the deep source region contacts the second channel region and the source extension region, and is vertically coincident with a first outer sidewall of the second dielectric gate spacer; and
a vertical sidewall of the deep drain region contacts the second channel region and the drain extension region, and is vertically coincident with a second outer sidewall of the second dielectric gate spacer.

10. The semiconductor structure of claim 2, wherein:
an entirety of a bottom surface of the first source contact via structure is located within an area defined by a periphery of a top surface of the first source region; and
an entirety of a bottom surface of the first drain contact via structure is located within an area defined by a periphery of a top surface of the first drain region.

11. The semiconductor structure of claim 10, wherein:
an entirety of an interface between the second source contact via structure and the deep source region is located within an area defined by a periphery of a top surface of the deep source region; and
an entirety of an interface between the second drain contact via structure and the deep drain region is located within an area defined by a periphery of a top surface of the deep drain region.

12. The semiconductor structure of claim 2, further comprising a contact-level dielectric layer overlying the semiconductor material layer and laterally surrounding the first source contact via structure and the first drain contact via structure, wherein the source-side dielectric liner and the drain-side dielectric liner have a respective annular top surface within a horizontal plane including a top surface of the contact-level dielectric layer.

13. The semiconductor structure of claim 2, further comprising a contact-level dielectric layer overlying the semiconductor material layer and laterally surrounding, and contacting sidewalls of, the first source contact via structure and the first drain contact via structure, wherein the source-side dielectric liner and the drain-side dielectric liner are planar dielectric liners having a respective shape of a plate having a uniform thickness between a top surface and a bottom surface.

14. A three-dimensional memory device, comprising:
a driver circuit comprising the semiconductor structure claim 1;
an alternating stack of insulating layers and word lines located over the semiconductor structure; and
memory stack structures extending through the alternating stack and comprising a respective memory film and a vertical semiconductor channel.

15. A method of forming a semiconductor structure, the method comprising:
forming a first gate structure of a first field effect transistor and a second gate structure of a second field effect transistor over a semiconductor material layer;
forming a first source region and a first drain region of the first field effect transistor and a source extension region and a drain extension region of the second field effect transistor within the semiconductor material layer;
forming a deep source region and a deep drain region of the second field effect transistor within the semiconductor material layer;
forming a contact-level dielectric layer over the first gate structure, the second gate structure, and the semiconductor material layer;
forming contact via cavities through the contact-level dielectric layer over the first source region, the first drain region, the deep source region, and the deep drain region;
forming a source-side dielectric liner on the first source region and forming a drain-side dielectric liner on the first drain region; and
forming contact via structures in the contact via cavities, wherein the contact via structures comprise a first source contact via structure overlying the first source region and vertically spaced from the first source region by the source-side dielectric liner, a first drain contact via structure overlying the first drain region and vertically spaced from the first drain region by a drain-side dielectric liner, a second source contact via structure contacting a top surface of the deep source region, and a second drain contact via structure contacting a top surface of the deep drain region.

16. The method of claim 15, wherein:
the semiconductor material layer has a doping of a first conductivity type; and
the first source region, the first drain region, the source extension region, the drain extension region are formed simultaneously by implanting electrical dopants of a second conductivity type that is an opposite of the first conductivity type through a first patterned implantation mask layer.

17. The method of claim 16, wherein:
the first source region, the first drain region, the source extension region, the drain extension region include electrical dopants of the second conductivity type at a first atomic concentration;
the deep source region and the deep drain region are formed by implanting additional electrical dopants of the second conductivity type through a second patterned implantation mask layer; and
the deep source region and the deep drain region include electrical dopants of the second conductivity type at a second atomic concentration that is greater than the first atomic concentration.

18. The method of claim 15, further comprising forming a first dielectric gate spacer around the first gate structure and forming a second dielectric gate spacer around the second gate structure by conformally depositing and anisotropically etching a dielectric material layer after formation of the first source region, the first drain region, the source extension region, and the drain extension region, and prior to formation of the deep source region and the deep drain region,
wherein:
the source extension region and the drain extension region are formed within portions of the semiconductor material layer that underlie peripheral portions of the second gate structure; and
the second dielectric gate spacer is formed on top surfaces of the source extension region and the drain extension region.

19. The method of claim 15, wherein the source-side dielectric liner, the drain-side dielectric liner, and the contact via structures are formed by:
depositing a continuous dielectric liner layer in the contact via cavities;
removing portions of the continuous dielectric liner that overlie the deep source region or the deep drain region;
depositing at least one conductive material in remaining volumes of the contact via cavities; and
removing portions of the continuous dielectric liner and the at least one conductive material from above a horizontal plane including a top surface of the contact-level dielectric layer, wherein:
remaining portions of the continuous dielectric liner comprise the source-side dielectric liner and the drain-side dielectric liner; and
remaining portions of the at least one conductive material comprise the contact via structures.

20. The method of claim 15, wherein the source-side dielectric liner, the drain-side dielectric liner, and the contact via structures are formed by:
oxidizing or nitriding surface portions of the first source region, the first drain region, the deep source region, and the deep drain region from underneath the contact via cavities, wherein oxidized or nitrided surface portions of the first source region and the first drain region comprise the source-side dielectric liner and the drain-side dielectric liner, respectively;
removing oxidized or nitrided surface portions of the deep source region and the deep drain region;
depositing at least one conductive material in remaining volumes of the contact via cavities; and
removing portions of the at least one conductive material from above a horizontal plane including a top surface of the contact-level dielectric layer, wherein remaining portions of the at least one conductive material comprise the contact via structures.
